(19) United States
(12) Patent Application Publication
(10) Pub. No.: US 2026/0358403 A1
(43) Pub. Date: Nov. 12, 2026

(54) Electromagnetic Interference Defect Models

(71) Applicant: Inventus Holdings, LLC, Juno Beach, FL (US)

(72) Inventors: Erina I Tamada-Wu, Palm Beach Gardens, FL (US); Chen Wang, Jupiter, FL (US); Dane M. McKoy, Coral Springs, FL (US); Gary Charles Griffith, Jupiter, FL (US)

(21) Appl. No.: 19/203,422

(22) Filed: May 9, 2025

(51) Int. Cl. G01R 31/28

(52) U.S. Cl. CPC G01R 31/2837; G01R 31/2846

(57) ABSTRACT

A system and method for detecting anomalous electrical equipment operating conditions. Zero span data is received from a receiver while the receiver is receiving Radio Frequency (RF) ElectroMagnetic Interference (EMI) energy emitted by a target electrical equipment at a detected frequency. The zero span data received from the receiver is analyzed by a data driven defects identification method. Whether or not a likely defect of the target electrical equipment exists is determined based on the analysis of the zero span data. An indication of the likely defect is provided based on determining a likely defect of the target electrical equipment exists.

### FIELD OF THE DISCLOSURE

The present disclosure generally relates to monitoring electrical equipment and, more particularly to identifying defects in operating electrical machinery.

### BACKGROUND

Monitoring operating electrical equipment, such as electrical generators, electrical motors, other machinery or equipment, or combinations of these, is able to provide indications of operational problems in an electrical equipment installation prior to the development of more significant failures in that installation. Conventional diagnosis of equipment problems relies on manual observation of the equipment or its operating characteristics to identify particular defects in the equipment. Such manual observations may be performed as part of periodic inspections or in response to indications of problems with the equipment. Such practices may result in the continued operation of equipment with a defect for a significant time before inspection and identification of a defect.

### BRIEF DESCRIPTION OF THE DRAWINGS

The accompanying figures, where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 illustrates a piece of electrical equipment with EMI monitoring equipment, according to an example.

FIG. 2 illustrates an EMI signature with abnormal spectral component, according to an example.

FIG. 3 illustrates a full EMI zero span dataset indicating a defect along with a zoomed in portion, according to an example.

FIG. 4 illustrates a defect identification process, according to an example.

FIG. 5 illustrates a received corona discharge zero span dataset, according to an example.

FIG. 6A depicts a pair of data reduced received corona discharge zero span datasets, according to an example.

FIG. 6B depicts a pair of normalized received corona discharge zero span datasets after data reduction, according to an example.

FIG. 6C depicts a pair of filtered corona discharge zero span datasets that are derived from the pair of normalized received corona discharge zero span datasets after data reduction depicted in FIG. 6B, according to an example.

FIG. 7 illustrates a corona discharge defect identification process, according to an example.

FIG. 8 illustrates a received arcing zero span dataset, according to an example.

FIG. 9 illustrates an arcing defect identification process, according to an example.

FIG. 10 illustrates a received exciter misfire zero span dataset, according to an example.

FIG. 11 illustrates a histogram of adjacent peak time separations within an EMI zero span dataset indicating an exciter misfire defect, according to an example.

FIG. 12 illustrates an exciter misfire defect identification process, according to an example.

FIG. 13 illustrates a block diagram of an example of an electronic device, according to an example.

### DETAILED DESCRIPTION

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting, but merely as a basis for the claims and as a representative basis for teaching one skilled in the art to variously employ the disclosed subject matter in virtually any appropriately detailed structure and function. Further, the terms and phrases used herein are not intended to be limiting, but rather to provide an understandable description.

### Non-Limiting Definitions

The terms “a” or “an”, as used herein, are defined as one or more than one. The term plurality, as used herein, is defined as two or more than two.

The term “adapted to” describes the hardware, software, or a combination of hardware and software that is capable of, able to accommodate, to make, or that is suitable to carry out a given function.

The term “another”, as used herein, is defined as at least a second or more.

The term “class” or “classifier” or “label” is a class label applied to data input in a machine learning model.

The term “configured to” describes hardware, software or a combination of hardware and software that is adapted to, set up, arranged, built, composed, constructed, designed, or that has any combination of these characteristics to carry out a given function.

The term “coupled,” as used herein, is defined as “connected,” although not necessarily directly, and not necessarily mechanically.

The term “electrical power operational modes of the AC machine” are the distinct output wattage ranges, e.g., (0, 5) MW, (150, 170) MW, (170, 190) MW, (190, 210) MW, (210, 230), MW, (230, 250) MW, (250, 270) MW, (270, 290) MW, (290, 310) MW, that the AC machine is capable of operating. The claimed invention is not limited to these example ranges and other ranges are within the scope of the claimed invention.

The terms “including” and “having,” as used herein, are defined as comprising (i.e., open language).

The term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

It should be understood that the steps of the methods set forth herein are not necessarily required to be performed in the order described, and the order of the steps of such methods should be understood to be merely exemplary. Likewise, additional steps may be included in such methods, and certain steps may be omitted or combined in methods consistent with various embodiments of the present device.

### Overview

The below described systems and methods operate to identify abnormal electrical equipment operations by receiving and automatically analyzing Electromagnetic Interference (EMI) signals emitted by operating electrical equipment. In an example, these EMI signals are radio frequency signals that exist over a wide bandwidth, such as between 50 KHz and 100 MHz. During normal operations, different pieces of equipment emit EMI signals with an RF frequency spectrum amplitude vs. frequency characteristic. A baseline RF frequency spectrum amplitude vs. frequency characteristic, or spectral envelope, for a particular piece of electrical equipment or for a category of similar electrical equipment is referred to as an EMI signature. An EMI signature generally indicates a range of spectrum amplitude values at each frequency component that statistically represents values that correspond to normal operations.

In some examples of the below described systems and methods, automated analysis of received EMI signals detects EMI signals emitted by a particular piece of electrical equipment that have frequency components with amplitudes outside of the expected envelope for the EMI signature of that particular piece of electrical equipment or for similar pieces of electrical equipment such as equipment with the same model number or design. In some examples, an EMI sensor, such as an electrical current transformer, is placed near pieces of electrical equipment being monitored to receive EMI signals generated by each piece of equipment. The received signals are automatically processed in an example by a scanning frequency receiver to monitor and characterize the EMI frequency spectrum over a specific RF spectrum. In various examples, the specific RF spectrum includes portions of the RF spectrum that contains EMI signals that indicate abnormal operations. Detected EMI signals with frequency components outside of an expected envelope for that particular piece or model of electrical equipment may indicate abnormal operations for the piece of equipment emitting that EMI signal and the presence of potential failure mechanisms due to electrical defects can be inferred.

In some examples of the below described systems and methods, operating abnormalities in a piece of electrical equipment, such as generators, are initially identified by analysis of EMI signatures against a baseline of observed EMI signatures for that particular piece of electrical equipment or of electrical equipment similar to that particular piece of electrical equipment. Once an abnormal EMI signature is identified, a nature of an abnormality for that piece of electrical equipment and one or more related likely defects are determined based on further EMI analysis.

In an example of the below described systems and methods, historical EMI signature data and their corresponding generator operational modes (out-of-service and active power output) are used to generate a baseline library for each generator in the fleet. In this library, each baseline signature is the statistical leverage of all the historical EMI signatures when the generator outputs a certain amount of active power and when the generator is out-of-service. A normality zone associated with each baseline is also established based on the statistical distribution of each data point on the signature curve.

In some examples, the below described systems and methods are able to be at least partially deployed to a cloud server where EMI signatures are collected from generation sites and measurement devices. The operational mode data may also be collected from other data management systems. The collected historical EMI signatures and the corresponding operational mode data in an example are used to establish a baseline library for each generator.

In an example, the below described systems and methods identify EMI frequency spectra determined for EMI signals received in the vicinity of an operating piece of electrical equipment that are not within an expected spectral envelope of the EMI signature for that particular piece of electrical equipment. In various examples, the automatic processing operates to identify a suspected EMI frequency spectrum component within an identified EMI frequency spectrum from a particular electrical generator that is outside of the expected spectral envelope for that particular electrical generator. In some examples, a scanning frequency receiver is used to collect the EMI frequency spectra.

In the following discussion, “zero span data” refers to time domain data collected while a receiver is set to a particular frequency to receive EMI energy emitted by a piece of electrical equipment. In an example, analysis of zero span data identifies operational abnormalities, such as defects, of the piece of electrical equipment emitting the EMI energy.

In an example, a processor analyzes zero span data to identify characteristics that correspond to previously identified defects in the electrical equipment producing that EMI signal. The analysis in some examples identifies likely defects of the electrical equipment being monitored based on received zero span data having characteristics similar to zero span data previously emitted by and received from similar equipment that had a similar defect. In an example, zero span data is collected over one second and analyzed to identify these likely abnormalities that are associated with previously identified defects.

In some examples, the below described systems and methods include analysis using data driven defects identification methods that in some cases include machine learning based models that analyze the zero span data collected for identified suspected EMI frequency spectrum components. In an example that monitors the operations of an electrical generator, machine learning models classify received zero span data representing EMI signals received from the generator, in which the machine learning models have been trained to recognize characteristics of received zero span data that are associated with two (2) possible electrical generator defect types. These two (2) defect types in an example have each been observed to have specific time domain patterns contained in zero span data for EMI spectral components that are outside of an expected EMI envelope. The two (2) defect types are: 1) Corona Discharge defects and 2) Arcing defects.

In some examples, further defects are recognized based on analysis by data driven analytical methods. In an example, exciter misfire defects are recognized by a data driven analytic method that recognizes patterns contained in zero span data that are consistent with an exciter misfire defects.

In an example, processing starts with preprocessing of zero span data that is received from a receiver. Such preprocessing in some examples prepares the received zero span data for analysis by machine learning models to classify characteristics of the data and includes data reduction, normalization, and low pass filtering of the received zero span data. In some examples, such preprocessing is performed prior to processing of the zero span data by data driven defects identification methods performed by machine learning based models. The preprocessing of data provided to different machine learning based models in some examples varies based upon the defect being classified by the particular machine learning model analyzing the data. Examples of such preprocessing are described below.

In some examples, machine learning based models analyze preprocessed zero span data to identify two of the three types of defects detected by the below described systems and methods. In other words, preprocessing is performed prior to processing of the zero span data by machine learning based models. In an example, machine learning based random forest classification models are trained to analyze zero span data to identify corona discharge defects and arcing defects. The analysis of zero span data to identify likely corona discharge in one example identifies a presence of sinusoidal waves in the zero span data. Analysis of the zero span data in one example identifies likely arcing by identifying a presence of large energy spikes in the zero span data.

Analysis of zeros span data to identify a likely presence of a third defect, exciter misfiring, includes using data driven analytic methods to detect an absence of one or more energy peaks that are expected to occur every 2.812 mS, which corresponds to occurrences at multiples of 360 cycles per second or Hertz (Hz). In an example, zero span data is analyzed to identify amplitude peaks that are consistent with exciter firing in an electrical motor. In various examples, any suitable technique is able to be used to identify such amplitude peaks. In an example, a histogram of time durations between the identified peaks is created once such amplitude peaks that are consistent with exciter firing are identified in the zero span data. The histogram is analyzed to determine an absence of such energy peaks to identify a likely presence of exciter misfiring.

An example processing flow for processing zero span data received from a piece of electrical equipment is summarized below.
1) Identify spectral component that is outside expected signature; and
2) Collect zero span data by tuning receiver on above spectral component.

Processing to Identify Corona Discharge is summarized below.
1) Identify portion of zero span data with highest energy level (highest amplitudes);
2) Reduce the number of samples in the dataset to restrict the dataset to include samples within a time span around the above identified portion with highest energy level (e.g., reduce 64K time samples to 18K samples) and normalize amplitudes of data samples in the reduced dataset;
3) Filter data using Low Pass filter (e.g., 3rd order Butterworth Lowpass Filter with bandwidth of 80 Hz);
4) Process low pass filtered data with a Random Forest classification model trained to identify Corona Discharge; and
5) Identify Corona Discharge defect based on Random Forest Classification Model output.

Processing to Identify Arcing is summarized below.
1) Identify portion of zero span data with highest energy level (highest amplitudes);
2) Reduce the number of samples in the dataset to restrict the data set to include samples within a time span around the above identified portion with highest energy level (e.g., reduce 64K time samples to 2.5K samples) and normalize amplitudes of data samples in the reduced dataset;
3) Filter data using Low Pass filter (e.g., 6th order Butterworth Lowpass Filter with bandwidth of 400 Hz);
4) Process low pass filtered data with a Random Forest classification model trained to identify Arcing; and
5) Identify Arcing defect based on Random Forest Classification Model output.

Processing to Identify Exciter Misfire is summarized below.
1) Identify exciter peaks in zero span data that are separated by multiples of at least 2.812 milliseconds (i.e., multiples of integer N of 1 or more);
2) Create histogram of time intervals between adjacent peaks in the zero span data;
3) Identify time intervals between adjacent peaks indicated in the histogram data that are multiples of 2.812 milliseconds (e.g., N); and
4) Identify, when exciter peaks have been identified, exciter misfire based on the number of adjacent peaks in the histogram that are N * 2.812 mS where N is greater than one.

The below described systems and methods provide an improved method and system that improves electrical equipment monitoring compared to conventional methods. Conventional methods rely on labor intensive and thus expensive analysis by highly skilled technicians to assess the health of electrical equipment such as an AC generator. The below described systems and methods provide an automated method to more continuously monitor the health of electrical equipment in contrast to the manual processes of conventional techniques.

### Electrical Equipment with EMI Monitoring Equipment

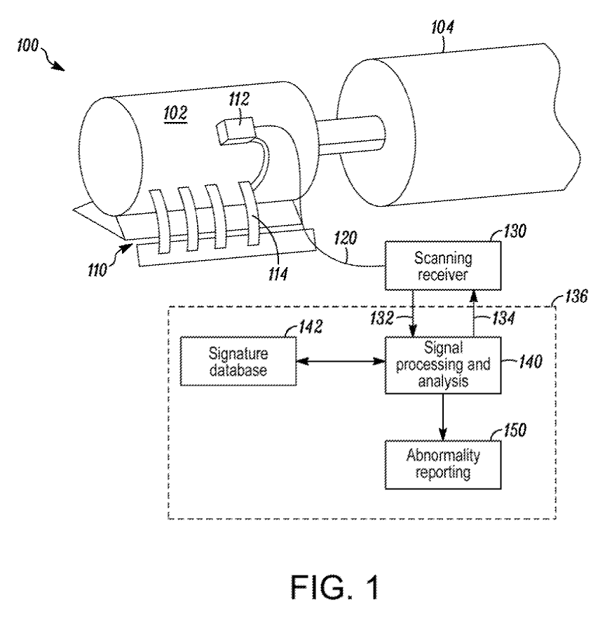

FIG. 1 illustrates a piece of electrical equipment with EMI monitoring equipment 100, according to an example. In the illustrated example, the piece of electrical equipment is a three-phase alternating current (AC) generator 102. The AC generator 102 in this example is driven by a turbine 104 and is an operating piece of electrical equipment that is operating to generate electricity. The three-phase AC generator provides three-phase electrical power through a four (4) wire power interface 110 that includes three power lines for the three phases and also includes a neutral connection 114. In the illustrated example, an RF current transformer 112 is coupled to the neutral connection 114.

The RF current transformer 112 provides a received RF signal, through an RF cable 120, to a scanning frequency receiver 130. The scanning frequency receiver 130 in an example scans across a specific RF spectrum that includes RF frequencies of interest to receive RF EMI energy over the RF spectrum that is received by the RF current transformer 112. In the illustrated example, the AC generator 102 is a target operating electrical equipment because it is being monitored for abnormal EMI signals as is described below.

The scanning frequency receiver 130 provides received signal data 132 to a signal processing and analysis component 140. In an example, the scanning frequency receiver 130 digitizes the signal received from the RF current transformer 112 to produce received signal data 132 that contains zero span data. The zero span data representing the received signal data 132 in an example is provided to the signal processing and analysis component 140 for processing and analysis as is described in detail below. The signal processing and analysis component 140 in an example is located in a data processing component 136. In various examples, the data processing component 136 is an example of an EMI signal processor that is able to be located in a facility with the AC generator 102, at a remote facility, at any location, or divided among these. A data communications component (not shown) provides communications between the scanning frequency receiver 130 and the data processing component 136 when the data processing component 136 is remotely located from the scanning frequency receiver 130.

The signal processing and analysis component 140 in an example provides commands 134 to control, for example, the scanning frequency receiver 130. In a monitoring mode, the signal processing and analysis component 140 causes, through commands 134, the scanning frequency receiver 130 to scan across a specified RF frequency band to monitor EMI signals. The signal processing and analysis component 140 in an example receives the received signal data 132 in the form of a zero span data that is a time series of data samples generated by the scanning frequency receiver 130. The signal processing and analysis component 140 in a monitoring mode processes the received signal data 132 to generate EMI spectra and signatures for the AC generator 102.

The signal processing and analysis component 140 in an example identifies when one or more components of a received EMI frequency spectrum is not within an expected spectral envelope of an EMI signature for the AC generator 102. In some examples, the signal processing and analysis component 140 is able to access a signature database 142 to retrieve stored EMI signature spectral data. In various examples, the data stored in the signature database 142 is able to be generated by any suitable technique such as accumulation of data from the AC generator 102 over time, from other processing and analysis components processing data from similar AC generators, by other techniques, or combinations of these.

When an EMI frequency spectrum is determined to not be within an expected spectral envelope of the EMI signature for the AC generator 102, the signal processing and analysis component 140 in an example performs processing to identify a detected frequency for further time domain signal processing. In an example, the signal processing and analysis component 140 identifies one or more received spectral component that are outside of the EMI envelope for the AC generator 102.

The signal processing and analysis component 140 then receives zero span data collected at the RF frequency of the identified received spectral component. The zero span data is then analyzed to determine likely defects in the AC generator 102 that may be a cause of the received spectral component that is outside of the EMI envelope for the AC generator 102. Examples of processing to analyze zero span data to identify a likely existence of one particular defect type is described in detail below.

Likely defects detected by the signal processing and analysis component 140 in an example are provided to an abnormality reporting component 150. The abnormality reporting component 150 in various examples provides one or more notifications of the identified likely defect. Such notifications are able to include, for example, electronic notifications to maintenance personnel, creation of repair orders to repair the suspected defect in the AC generator 102, other notifications, or combinations of these.

### EMI Signature Data Example and Overview of Abnormality Processing

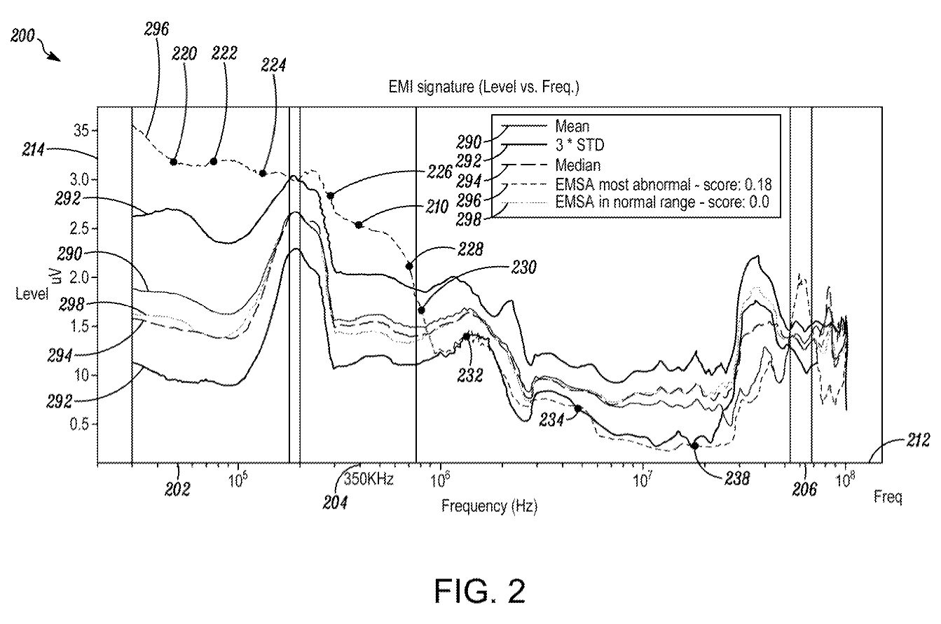

FIG. 2 illustrates an EMI signature with abnormal spectral component 200, according to an example. The EMI signature with abnormal spectral component 200 is an example of data compiled by the above described signal processing and analysis component 140 based on data received from the scanning frequency receiver 130 while scanning a range of RF frequencies received by the RF current transformer 112.

The EMI signature with abnormal spectral component 200 is an example of an EMI signature such as for the above described AC generator 102. In the case of the EMI signature with abnormal spectral component 200 depicting EMI spectral data received from the AC generator 102, the EMI signature with abnormal spectral component 200 illustrates a baseline of EMI signals emitted by the AC generator 102 at a given operational mode. Shown are various statistical calculations, including the calculated mean trace 290, a pair of standard deviations with a 3 sigma (σ) confidence level traces 292, a median value trace 294, a most abnormal score trace 296, i.e., a score that deviated most from the normal range, and a normal range score trace 298. RF frequencies of the spectral components are shown along a horizontal frequency axis 212 with the amplitude level of the frequency components shown along a vertical level axis 214.

The most abnormal score trace 296 exceeds bounds of expected EMI energy at frequency components that are within abnormality frequency zones 202, 204 and 206. A number of value points with equal frequency value spacing along the most abnormal score trace 296 are shown. The EMI signature with abnormal spectral component 200 depicts a first value point 220, a second value point 222, a third value point 224, a fourth value point 226, a selected value point 210, and a fifth value point 228 on the most abnormal score trace 296 that occur at points where the most abnormal score trace 296 is outside of the 3 sigma (σ) confidence level traces 292. A sixth value point 230, a seventh value point 232, an eighth value point 234, and a ninth value point 238 are at frequency points where the most abnormal score trace 296 is within the 3 sigma (σ) confidence level traces. These value points reflect EMI signal frequency components that are outside of the 3 sigma (σ) confidence level traces 292 of the baseline EMI signature of the AC generator 102 operating at given operation mode, such as an amount of electrical output power. In the depicted example, the selected value point 210 is selected for further processing because it is the value point with a value that is furthest from the 3 sigma (σ) confidence level traces 292. The selected value point 210 is shown to occur at an RF frequency of three hundred and fifty Kilohertz (350 KHz). Because the selected value point 210 is most distant from the 3 sigma (σ) confidence level traces 292, it is determined to be the detected frequency. The EMI signal at the RF frequency of the selected value point 210, the detected frequency in this example, is further analyzed as described below.

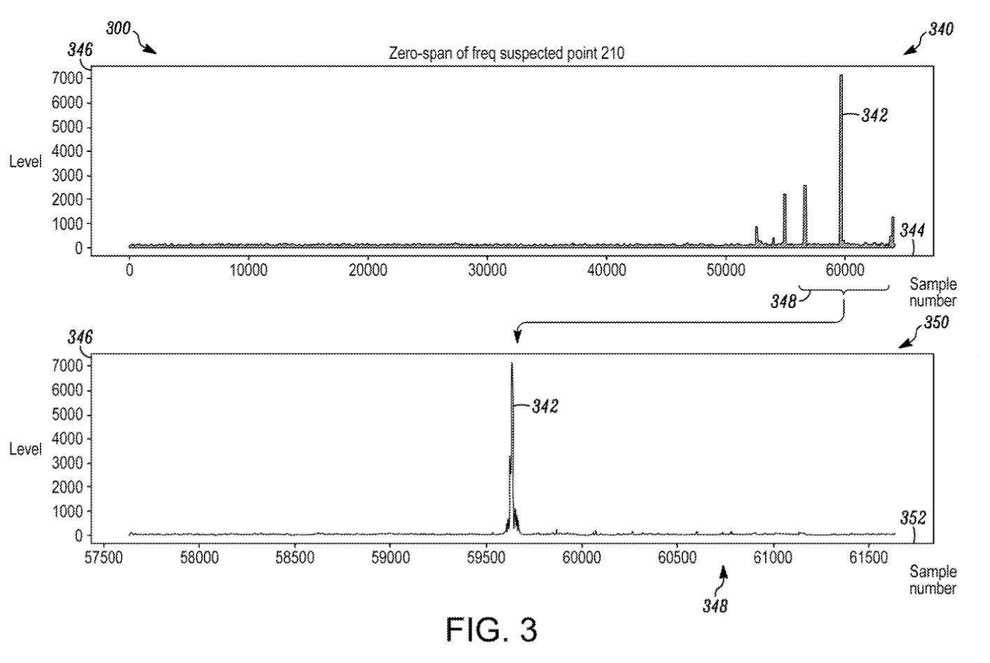

FIG. 3 illustrates a full EMI zero span dataset with zoomed in portion 300 indicating a defect, according to an example. The full EMI zero span dataset with zoomed in portion 300 include a full zero span dataset 340 and a partial zero span dataset 350 that includes a portion of the full zero span dataset 340. The full EMI zero span dataset with zoomed in portion 300 depicts zero span data produced by, for example, the scanning frequency receiver 130. In the illustrated example, the full EMI zero span dataset with zoomed in portion 300 depicts zero span data that has been received when the scanning frequency receiver 130 is set to receive signals at three hundred and fifty Kilohertz (350 KHz), which corresponds to the detected frequency that is the RF frequency corresponding to the above described selected value point 210 of the EMI signature with abnormal spectral component 200.

In the illustrated example, the full zero span dataset 340 illustrates zero span data that covers one second (1 Sec.) as was produced by the scanning frequency receiver 130. In the illustrated example, the scanning frequency receiver 130 samples its received waveform at sixty-four thousand samples per second (64 Ksamp/S). The full zero span dataset 340 thus shows sixty four thousand (64,000) samples along the full sample number axis 344. The full zero span dataset 340 further has a level axis 346 that depicts the quantized value of each of the 64,000 samples along the sample number axis 344.

The full zero span dataset depicts a signal amplitude spike 342 near the right end of the illustrated sample number axis. In order to more efficiently process this zero span data, processing identifies a signal amplitude spike 342 within a full set of zero span data and continues to process a subset of the full set of zero span data. In the illustrated example, a selected subset 348 of zero span data is identified that is centered around the identified signal amplitude spike 342. This selected subset 348 is depicted as the partial zero span dataset 350. The partial zero span dataset 350 depicts a partial sample number axis 352 that extends from sample number 57,500 to sample number 61,500. The identified signal amplitude spike 342 is contained within the partial zero span dataset 350. In an example, the partial zero span dataset 350 includes consecutive samples of the full zero span dataset 340 that are in the vicinity of the identified signal amplitude spike 342.

The partial zero span dataset 350 is an example of a data reduced dataset of the full zero span dataset 340. In various examples, preprocessing the full zero span dataset 340 by reducing the number of samples in the dataset to create the partial zero span dataset 350 advantageously improves efficiency by reducing the amount of data to process or analyze and focuses processing or analysis resources on more relevant portions of received data. Focusing the dataset to be analyzed on the portion of relevant zero span data that may indicate defects further improves the performance of the analyses performed by machine learning models to classify the data.

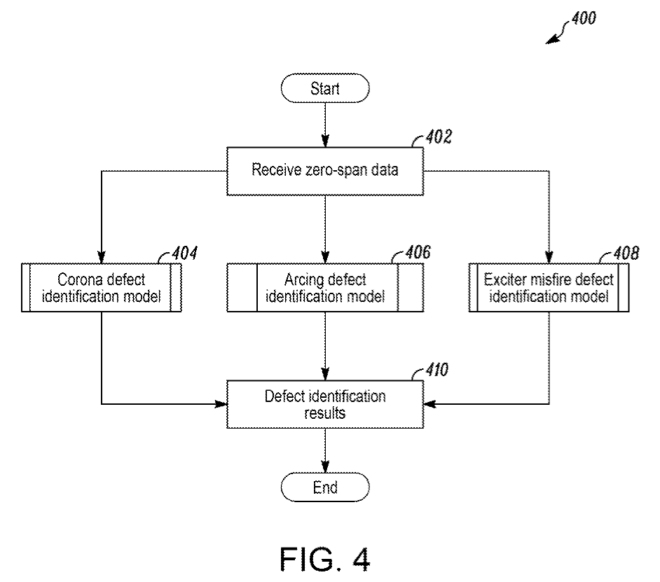

FIG. 4 illustrates a defect identification process 400, according to an example. The defect identification process 400 depicts an example of processing performed by the above described signal processing and analysis component 140 to identify a possible defect in a piece of electrical equipment based on EMI signals emitted by that piece of equipment.

The defect identification process 400 receives, at 402, zero span data for a piece of target electrical equipment. An example of zero span data is described above with regards to the full zero span dataset 340. In an example, the zero span data is received after an EMI signal frequency component is determine to be outside of an EMI signature for the piece of target electrical equipment given its operating mode, such as is described above.

The illustrated defect identification process 400 proceeds to analyze, by a data driven defects identification method, the zero span data received from the receiver. Such analyses include processing of the received zero span data to determine whether or not a likely defect of the target electrical equipment exists. In an example, such analysis supports determinations to identify one of three (3) defects in an AC generator. The defect identification process 400 in an example identifies a likely corona discharge defect in the AC generator by processing the received zero span data with a corona defect identification model, at 404. The defect identification process 400 identifies a likely arcing defect in the AC generator by processing the received zero span data with an arcing defect identification model, at 406. The defect identification process 400 also identifies a likely exciter misfire defect in the AC generator by processing the received zero span data with an exciter misfire defect identification model, at 408.

The corona defect identification model, arcing defect identification model, and the exciter defect identification model are examples of data driven defects identification methods. The various types of processing of zero span data that is performed by these methods are examples of applying these models to determine a likely defect of the target electronic equipment based on analysis of zero span data received from a receiver based on performing a data driven defect identification method.

In some examples, the likely corona discharge defect is identified based on analysis performed by a first random forest classification model that is trained to classify zero span data as indicating a corona discharge defect and a likely arcing defect is identified based on analysis performed by a second random forest classification model that is trained to classify received RF EMI zero span data as indication an arcing defect. In an example, the likely exciter misfire defect is identified based on analyzing zero span data with data driven analytical methods.

Defect identification results are determined, at 410. In an example, the defect identification results are determined by respective classifications of the first random forest classification model and the second random forest classification model, the likely defect to be at least one of the corona discharge defect or the arcing defect, and further based on results from the data driven analytical methods that the likely defect is an exciter misfire defect. The defect identification process 400 then ends.

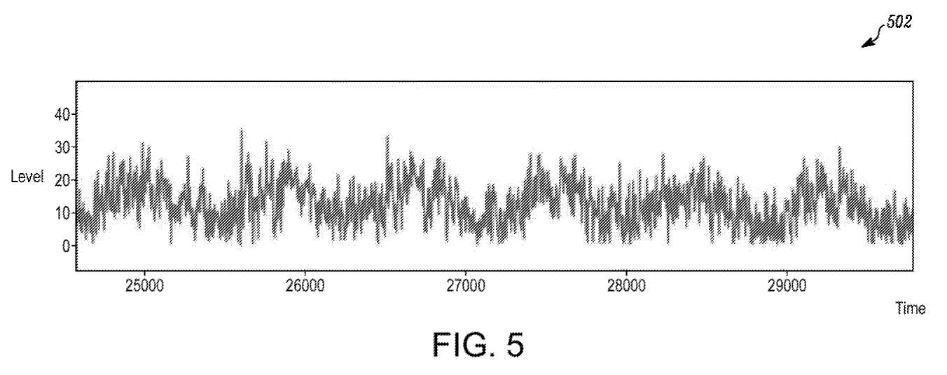

FIG. 5 illustrates a received corona discharge zero span dataset 500, according to an example. The received corona discharge zero span dataset 500 is a further example of a zero span dataset, such as are described above, that is produced by the scanning frequency receiver 130 when it is in a zero span data collection mode. The illustrated corona discharge zero span dataset 500 depicts one second of received signal data.

The corona discharge zero span dataset 500 is an example of a zero span dataset that reflects a received EMI signal that indicates the presence of a corona discharge defect within an AC generator. The illustrated corona discharge zero span dataset 500 is raw received data that has not been preprocessed. In an example, as noted above, a scanning frequency receiver 130 produces a time sequence of data samples that is sampled at sixty four (64) thousand samples per second. It has been observed that a corona discharge defect in an AC generator results in a sinusoidal waveform on the received EMI signal as is depicted by the received corona discharge zero span dataset 500.

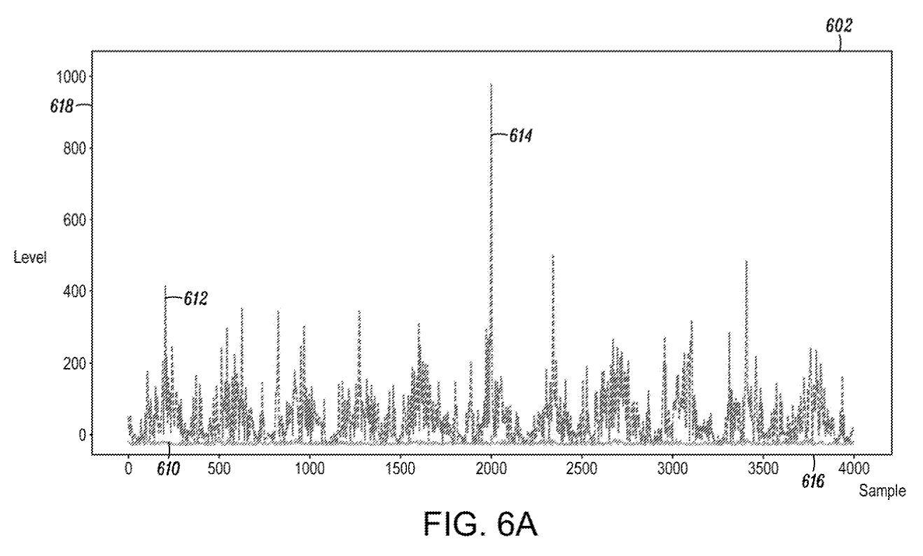

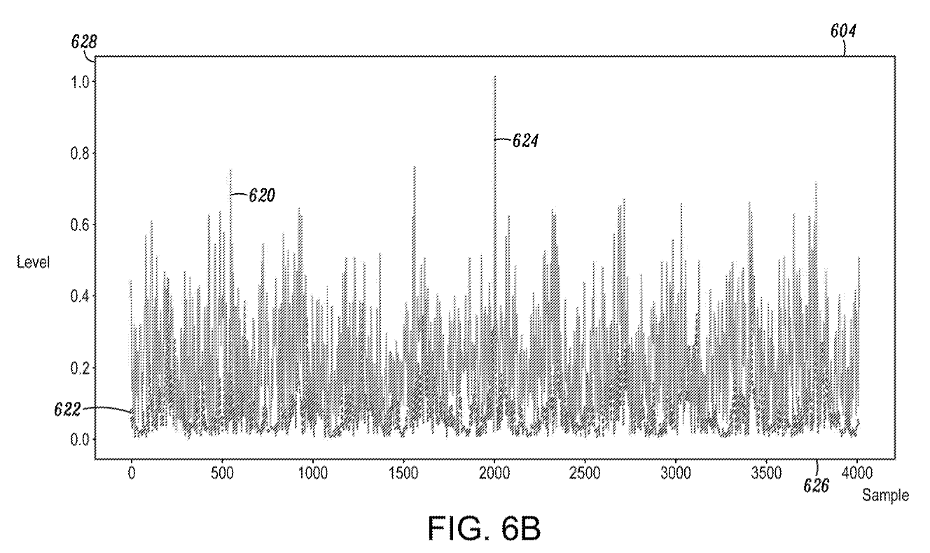

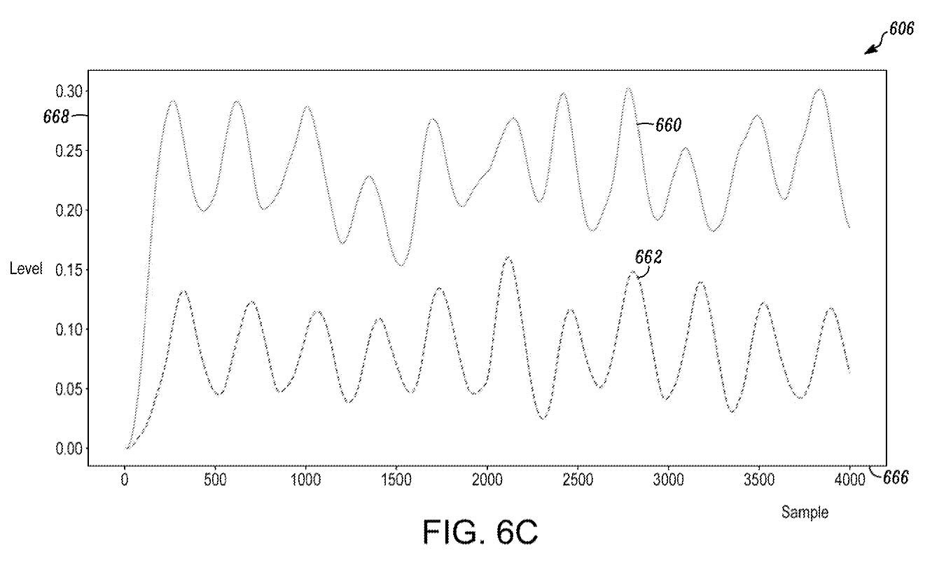

FIG. 6A depicts a pair of data-reduced, received corona discharge zero span datasets 602, according to an example. The pair of data-reduced, received corona discharge zero span datasets 602 depicts two zero span datasets, a first zero span dataset 610 and a second zero span dataset 612, that have had their number of data samples reduced to a subset of data that encompasses a data peak 614. Data reduction in this example refers to reducing zero span data by retaining a determined number of samples that include a portion of interest and discarding the other samples of the dataset. In an example, data reduction of a received corona discharge zero span dataset includes preprocessing of the corona discharge zero span dataset 500 by reducing the zero span data from having sixty four thousand (64,000) samples for one (1) second of data to a shortened set of zero span data that has four (4) thousand samples, which corresponds to retaining less than one third of samples within the received zero span data.

The pair of data-reduced, received corona discharge zero span datasets 602 has a sample axis 616 that depicts the sample number of the data-reduced datasets, and a level axis 618 that depicts the amplitude level of each data sample. The sample axis 616 extends from zero (0) to four thousand (4,000) to correspond to the number of samples contained in the data-reduced datasets. The level axis 618 extends from values zero (0) to one thousand (1000) and corresponds to the raw amplitude data contained in the zero span datasets.

In this example, as is shown by the pair of data-reduced, received corona discharge zero span datasets 602, the original data for the first zero span dataset 610 has different amplitude levels than the original data for the second zero span dataset 612. This amplitude disparity is able to affect comparison of these datasets to identify signal characteristics that may indicate a defect. In order to improve processing and analysis of these datasets, the amplitude values of first zero span dataset 610 and the second zero span dataset 612 are normalized to facilitate comparison of their features. In an example, normalizing the zero span data is performed after reducing the zero span data and includes adjusting the amplitude of sample values so that a maximum value sample in each data-reduced data subset has a value of one (1.0) and other values are fractional values of this maximum value. The normalization in this example results in the normalized datasets having values between zero (0) and one (1.0).

FIG. 6B depicts a pair of normalized, received corona discharge zero span datasets after data reduction 604, according to an example. The normalized, received corona discharge zero span datasets after data reduction 604 depicts a data reduced and normalized first zero span dataset 620 and a data reduced and normalized second zero span dataset 622. The depicted data are normalized values determined for the above described first zero span dataset 610 and second zero span dataset 612.

The normalized received corona discharge zero span datasets after data reduction 604 has a sample axis 626 that depicts the sample number of the data reduced datasets, and a level axis 628 that depicts the amplitude level of each data sample. The sample axis 626 extends from zero (0) to four thousand (4,000) to correspond to the number of samples contained in the data reduced datasets as is shown for the pair of data reduced, received corona discharge zero span datasets 602. The level axis 618 extends from values zero (0) to one (1.0) to correspond to the normalized amplitude values that are used for further processing in some examples.

The example data depicted by the pair of normalized, received corona discharge zero span datasets after data reduction 604 includes noise that obscures the sinusoidal waveform of the received EMI signal. Low pass filtering is applied to such datasets in some examples to reduce the noise contained in these datasets as is described below.

FIG. 6C depicts a pair of filtered corona discharge zero span datasets 606 that are derived from the pair of normalized, received corona discharge zero span datasets after data reduction 604 depicted in FIG. 6B, according to an example. The filtered corona discharge zero span datasets 606 depicts a first filtered corona discharge zero span dataset 660 and a second filtered corona discharge zero span dataset 662. The pair of filtered corona discharge zero span datasets 606 depict corona discharge zero span datasets that have been data reduced and normalized, as described above, and then lowpass filtered to reduce the noise level present in the datasets. Reducing the noise level present in the data sets improves a likelihood of identifying the presence of a sinusoidal waveform in these datasets.

The pair of filtered corona discharge zero span datasets 606 has a sample axis 666 that extends from zero (0) to four thousand (4,000) as is consistent with the above described pair of data-reduced, received corona discharge zero span datasets 602 and the pair of normalized, received corona discharge zero span datasets after data reduction 604. The pair of filtered corona discharge zero span datasets 606 has a level axis 668 that extends from zero (0.00) to thirty hundredths (0.30) to correspond to levels produced by the low pass filter processing of the pair of normalized received corona discharge zero span datasets after data reduction 604.

The depicted filtered corona discharge zero span datasets 606 are obtained by filtering the data reduced and normalized datasets with a third order Butterworth lowpass filter that has a cut-off frequency of eighty (80). Selection of a lowpass filter with these characteristics has been found to improve the performance of machine learning based models in identifying corona discharge defects in zero span EMI data.

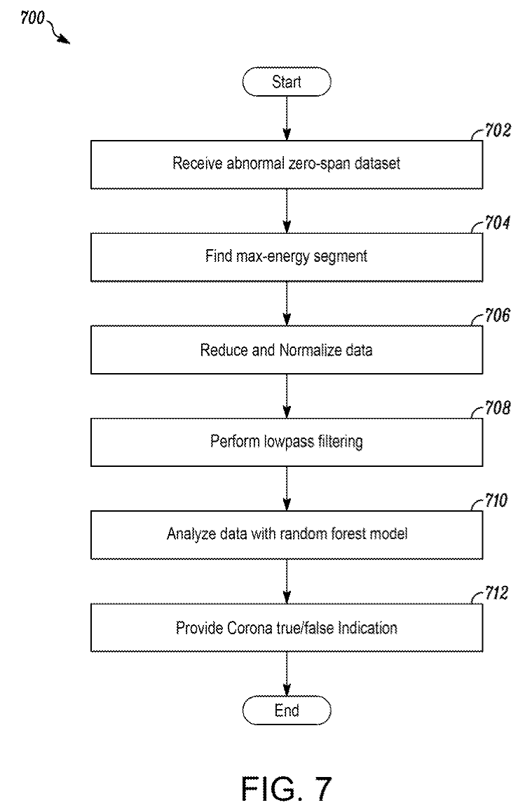

FIG. 7 illustrates a corona discharge defect identification process 700, according to an example. The corona discharge defect identification process 700 in an example is performed by the signal processing and analysis component 140 described above.

The corona discharge defect identification process 700 receives, at 702, an abnormal zero span dataset. In an example, abnormal zero span datasets are identified based on determining a frequency component with energy outside of the EMI signature for the piece of electrical equipment being monitored. Such datasets are described above, such as the received corona discharge zero span dataset 500.

The corona discharge defect identification process 700 finds, at 704, a maximum energy segment. The maximum energy segment is an example of a high energy segment within the zero span data and in an example corresponds to datapoints within the received corona discharge zero span dataset 500 that indicate a highest energy component, e.g., datapoints that have a high amplitude over a period of time relative to other datapoints in the data set

The corona discharge defect identification process 700 data reduces and normalizes, at 706, the zero span data. An example of such data reduction and normalization is described above. The data reduced and normalized data is filtered using a lowpass filter, at 708. As described above, in an example the data reduced and normalized data is filtered using a lowpass filter by a third order Butterworth filter with a cutoff frequency of 80.

The low pass filtered data is then analyzed by a random forest model, at 710. In an example, the random forest model is a random forest classification model that includes a machine learning model that combines the output of multiple decision trees that are trained during a training phase to provide a likely classification output such as a likelihood indication that the received corona discharge zero span dataset 500 indicates EMI energy that is generated by a corona discharge defect.

Based on the results of the random forest model analysis, a true or false indication of the existence of a corona defect is provided, at 712. This indication in some examples is provided to the abnormality reporting component 150 described above.

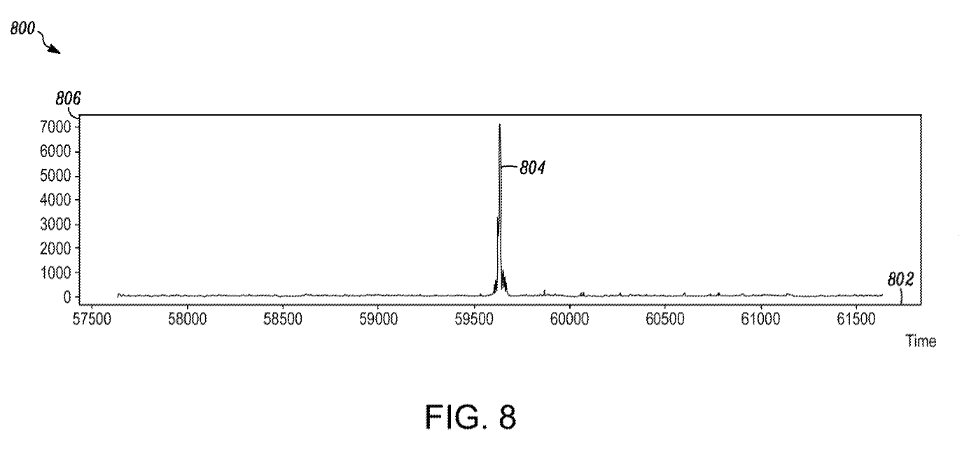

FIG. 8 illustrates a received arcing zero span dataset 800, according to an example. The received arcing zero span dataset 800 is a further example of zero span data contained within a zero span dataset, such as are described above, that is produced by the scanning frequency receiver 130 when it is in a zero span data collection mode that produces zero span data containing data samples of a received RF signal at a fixed frequency. The received arcing zero span dataset 800 includes a horizontal sample count axis 802 that indicates the sample number of data points in the zero span data and a vertical value axis 806 that indicates the value of each depicted sample. It is to be noted that the illustrated arcing zero span dataset 800 corresponds to the partial zero span dataset 350 described above and depicts a data reduced dataset.

The arcing zero span dataset 800 is an example of a zero span dataset that reflects a received EMI signal that indicates the presence of an arcing defect within an AC generator. In an example, as noted above, a scanning frequency receiver 130 produces a time sequence of data samples that is sampled at sixty four (64) thousand samples per second. It has been observed that an arcing defect in an AC generator causes an EMI signal to have a large energy spike characteristic in the received EMI signal as is depicted by the energy spike 804 in the received arcing zero span dataset 800.

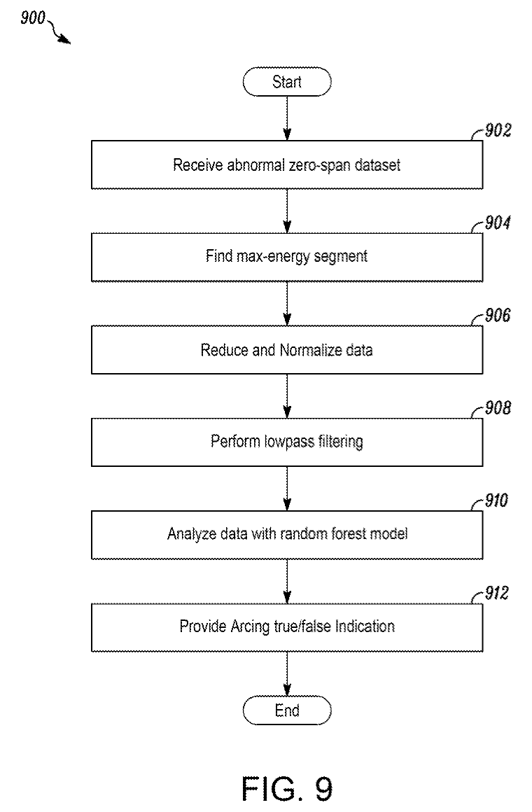

FIG. 9 illustrates an arcing defect identification process 900, according to an example. The arcing defect identification process 900 in an example is performed by the signal processing and analysis component 140 described above.

The arcing defect identification process 900 receives, at 902, an abnormal zero span dataset. In an example, abnormal zero span datasets are identified based on determining a frequency component with energy outside of the EMI signature for the piece of electrical equipment being monitored. Such datasets are described above such as the arcing zero span dataset 800.

A maximum energy segment is found, at 904, in the received abnormal zero span dataset. The arcing defect identification process 900 finds, at 904, a maximum energy segment. The maximum energy segment is an example of a high energy segment within the zero span data and in an example corresponds to datapoints within that have a high amplitude relative to other datapoints in the zero span data, such as the energy spike 804 described above.

The received abnormal zero span dataset is data reduced and normalized, at 906. Such data reduction in an example includes reducing the sixty four (64) thousand samples of the received one second of received EMI signal to two thousand five hundred (2,500) samples points, which corresponds to retaining less than one twenty-fifth of the samples within the received zero span data. Normalization includes scaling the data values to have values between common maximum and minimum value, such as zero (0) and one (1).

In an example, after normalization, the normalized dataset is filtered using a low pass filter, at 908. In an example of identifying an arcing defect, the normalized abnormal zero span dataset is filtered with a sixth order Butterworth lowpass filter with a cut off frequency of 400.

The low pass filtered zero span dataset is then analyzed by a random forest model, at 910. In an example, the random forest model is a random forest classification model that includes a machine learning model that combines the output of multiple decision trees that are trained during a training phase to provide a classification output such as a likelihood indication that the arcing zero span dataset 800 indicates EMI energy that is generated by an arcing defect.

Based on the results of the random forest model analysis, a true or false indication of the existence of an arcing defect is provided, at 912. This indication in some examples is provided to the abnormality reporting component 150 described above.

The above described processing methods and parameters incorporated into the above described systems and methods associated with processing zero span data to determine a likely presence of a corona defect or arcing defect have been selected based on evaluation of the classification performance produced by using of various parameters and classification methods. This evaluation of proposed processing methods and parameters included evaluating variations of several preprocessing parameters including a) data reduction size, which is the length of data vector to be kept from the original zero-span data; b) low-pass filter order; and c) low-pass filter cut-off frequency. This evaluation further evaluated the classification performance of various classification methods. An example of an evaluation process is described below.

A training data set containing a number of example zero span data sets, where each example zero span data set includes sixty-four thousand (64,000) samples, was created and processed by systems and methods that are configured to use various combinations of preprocessing parameters and classification methods. Preprocessing parameter values selected in one example are described below.

A number of candidate data reduction values were selected for evaluation that each correspond to the number of data samples from the sixty-four thousand (64,000) samples of each example zero span data set that are to be further processed. Examples of data reduction are described above. Candidate data reduction values of three thousand (3,000), four thousand (4,000), five thousand (5,000), six thousand (6,000), eight thousand (8,000), ten thousand (10,000), fourteen thousand (14,000), sixteen thousand (16,000), eighteen thousand (18,000), twenty thousand (20,000) were selected in an example.

The evaluation, in an example, selected candidate low-pass filter cut-off frequency values of thirty Hertz (30 Hz), sixty Hertz (60 Hz), seventy Hertz (70 Hz), eighty Hertz (80 Hz), ninety Hertz (90 Hz), one hundred Hertz (100 Hz), two hundred Hertz (200 Hz), three hundred Hertz (300 Hz), and four hundred Hertz (400 Hz).

The evaluation, in an example, selected candidate low pass filter order values of two (2), three (3), four (4), five (5) and six (6).

In an example, the evaluation iteratively preprocessed each example zero span data set, according to a process similar to the above described preprocessing, by using each combination of the above preprocessing values. Each of the preprocessed example zero span data sets was then processed by using each of a number of different classification models that included random forest classification models, deep neural network classification models, XGBoost Decision Trees, and Regular Decision Trees. An example of one such combination is able to be described as: low-pass filter cut-off frequency=30Hz, reduction size=6000, low-pass filter order= 5, method= ‘Deep Neural Networks.’ The evaluation in an example created other combinations that each include a combination of each of the above listed candidate preprocessing values and classification models.

The evaluation in an example performed training of the classification models with a five (5) fold cross-validation framework. An example of this five (5) fold cross-validation framework includes performing the following for all combinations of parameters and classification methods.
A. Select one of all the combinations of pre-processing parameters and select one classification method.
B. Pre-process each data point in the training dataset.
C. Split the pre-processed training dataset into five (5) portions and give them identification numbers from one (1) to five (5).
D. Set one (1) as the number of the current portion.
E. Pick the current portion as the current validation dataset.
F. Use the other four (4) portions of data as a current training dataset and train the machine learning model with the selected classification method.
G. Use the current validation dataset to test the results of the classification method using the F1 score as an evaluation method and record model performance for this iteration.
H. Check if every portion of data has served as validation dataset.
   i. If not, increase current portion number by 1 and go to step E.
   ii. Else, collect performance record for each iteration and average them.
I. Report the average as final performance for this combination of pre-processing parameters with the selected classification method and mark the current pre-processing parameter combination with the selected classification method as visited.

The evaluation selected the combination of parameters and classification method that produced the highest F1 score.

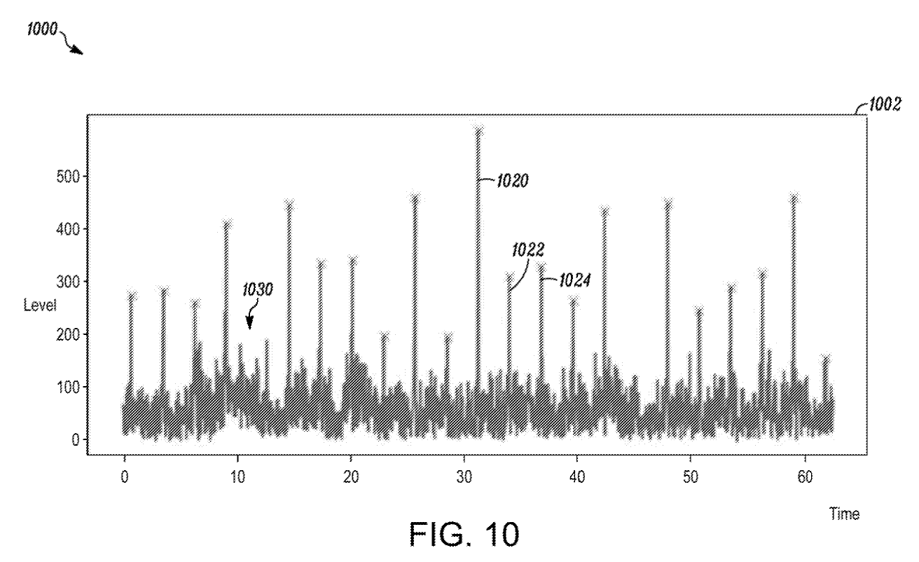

FIG. 10 illustrates a received exciter misfire zero span dataset 1000, according to an example. The received exciter misfire zero span dataset 1000 is a further example of a zero span dataset, such as are described above, that is produced by the scanning frequency receiver 130 when it is in a zero span data collection mode that produces zero span data containing data samples of a received RF signal at a fixed frequency. The illustrated exciter misfire zero span dataset 1000 depicts one second of received signal data.

The exciter misfire zero span dataset 1000 depicts an example of a zero span dataset that reflects a received EMI signal that indicates the presence of an exciter misfire defect within an AC generator. Exciter misfires are defects that happen when peaks within the normal exciter patterns are skipped. In an example of an AC generator generating three-phase electricity at sixty (60) Hertz, exciter peaks are observed as amplitude peaks in received zero span EMI signals at multiples of three hundred and sixty (360) Hertz, or approximately every 2.812 milliseconds (mS), to form a normal pattern. It has been observed that an exciter misfire defect in an AC generator can be identified by an energy peak missing from this expected 2.812 mS cadence.

The exciter misfire zero span dataset 1000 depicts a received number of exciter peaks, including a first peak 1020, a second peak 1022, and a third peak 1024 that are among a number of other exciter peaks that are generally present with spacing separated by 2.812 mS within the zero span data of the exciter misfire zero span dataset 1000. The exciter misfire zero span dataset 1000 further shows a missing peak 1030. Aside from the portion of the exciter misfire zero span dataset 1000 at the missing peak 1030, the exciter peaks form a normal pattern of periodically occurring within 2.812 mS intervals between the peaks. The lack of an exciter peak in the exciter misfire zero span dataset 1000 indicates an exciter misfire at the time of the missing peak 1030 and thus an exciter misfire defect can be identified based on that feature of the exciter misfire zero span dataset.

In some examples, a preliminary determination is performed to determine whether exciter peaks are present in the exciter misfire zero span dataset 1000. In an example, the presence of exciter peaks is determined based on determining that the exciter misfire zero span dataset 1000 contains a number of adjacent peaks that are separated by 2.812 mS where that number is above a particular percentage. In an example, exciter peaks are determined to exist in an exciter misfire zero span dataset 1000 if the dataset contains at least seventy five percent (75 %) of adjacent peaks that are separated by 2.812 mS.

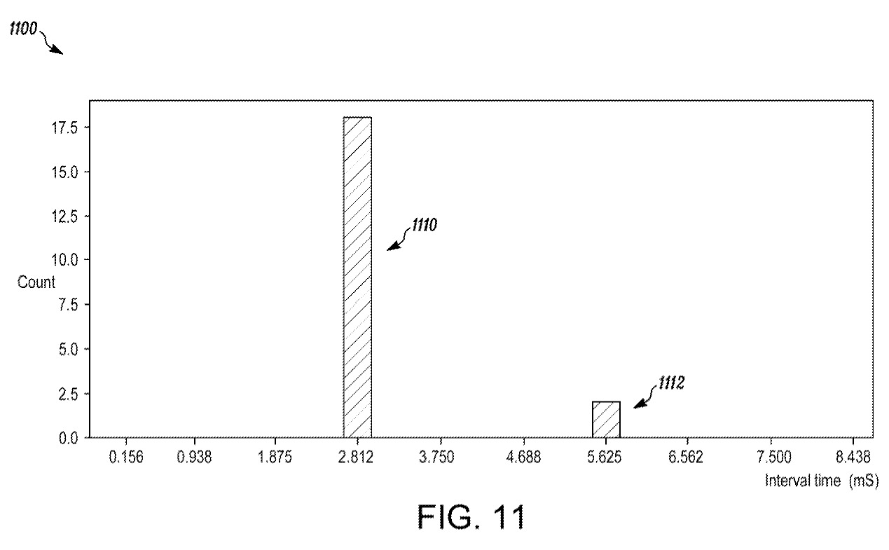

FIG. 11 illustrates a histogram of adjacent peak time separations within an EMI zero span dataset indicating an exciter misfire defect 1100 for the exciter misfire zero span dataset 1000, according to an example. The histogram of adjacent peak time separations within an EMI zero span dataset indicating an exciter misfire defect 1100 indicates time intervals between detected amplitude peaks of the exciter misfire zero span dataset 1000. The histogram of adjacent peak time separations within an EMI zero span dataset indicating an exciter misfire defect 1100 has a first interval count line 1110 that shows that a number of detected amplitude peaks occur at an interval of 2.812 mS. The presence of a number of detected amplitude peaks that occur at an interval of 2.812 mS is an indication of exciter peaks being present in the data and is a condition to further identifying missing exciter peaks in order to further determine the presence of an exciter misfire defect.

A second interval count line 1112 indicates that a pair of amplitude peaks occurred with an interval between them of 5.625 mS, which is twice the time interval of the 2.82 mS that corresponds to the normal exciter pattern. This time interval of 5.625 mS corresponds to the missed peak 1030 described above. In an example, analysis is able to identify an exciter misfire defect based on the extended time interval indicated by the second interval count line 1112.

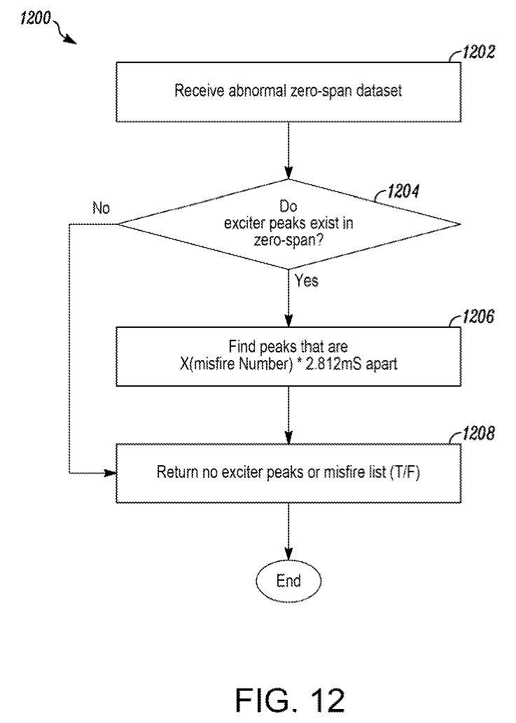

FIG. 12 illustrates an exciter misfire defect identification process 1200, according to an example. The exciter misfire defect identification process 1200 in an example is performed by the signal processing and analysis component 140 described above.

The exciter misfire defect identification process 1200 receives, at 1202, an abnormal zero span dataset. In an example, abnormal zero span datasets are identified based on determining a frequency component with energy outside of the EMI signature for the piece of electrical equipment being monitored. Such datasets are described above such as the exciter misfire zero span dataset 1000.

The received abnormal zero span dataset is analyzed, at 1204, to determine if the dataset contains exciter peaks. Such analysis is able to be performed by analysis of the received abnormal zero span dataset to identify the peaks that are separated by a minimum time duration between adjacent amplitude peaks of the expected time interval, such as 2.812 mS. In an example, if a proportion of identified peaks are separated from other peaks by an interval of about 2.812 mS, the abnormal zero span dataset is determined to contain exciter peaks. In an example, if a proportion of seventy five percent (75%) of identified peaks are separated by about 2.812 mS, a determination is made that the dataset contains exciter peaks. If it is determined that the dataset does not contain exciter peaks, the exciter misfire defect identification process 1200 returns, at 1208, with an indication that the received abnormal zero span dataset does not contain exciter data.

If it is determined, at 1204, that the received abnormal zero span dataset does contain exciter data, the exciter misfire defect identification process 1200 finds, at 1206, peaks that are separated by minimum time durations that are integer multiples of the expected time interval. In an example, peaks at integer multiples of 2.812 mS as expected for exciter peaks for a sixty (60) Hertz AC generator are found where the integer “x” is greater than 1. In some examples, finding peaks includes creating a histogram of amplitude peaks in the zero span data that are separated by minimum time durations that are integer multiples of 2.812 mS; determining that amplitude peaks in the histogram are separated by integer multiples of 2.812 mS; and identifying, based on determining that amplitude peaks in the histogram are separated by integer multiples of 2.812 mS, the likely defect as an exciter misfire defect based the histogram of amplitude peaks indicating peaks separated by minimum time durations that are integer multiples of 2.812 mS wherein the integer multiple is greater than one.

The exciter misfire defect identification process 1200 then returns, at 1208, with an indication that a misfire occurred by providing a list of the number of misfires that the received abnormal zero span dataset does not contain exciter data. The exciter misfire defect identification process 1200 then ends.

### Information Processing System

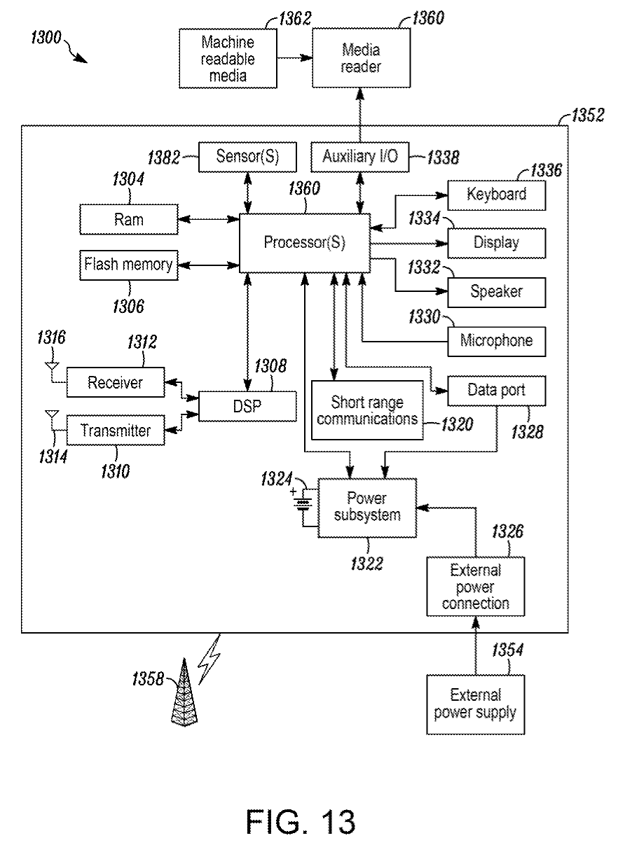

FIG. 13 illustrates a block diagram of an example of an electronic device 1300, according to an example. In various examples, the electronic device is able to be a computer, including laptop computer or other portable device, such as a smartphone, that may run software to carry out any of the above described processing. The electronic device 1300 may communicate over a wired or wireless network to one or more radio frequency current transformers coupled too one of a ground or a neutral line of an AC machine. The system may incorporate communication subsystem elements such as a wireless transmitter 1310, a wireless receiver 1312, and associated components such as one or more antenna elements 1314 and 1316. A digital signal processor (DSP) 1308 performs processing to extract data from received wireless signals and to generate signals to be transmitted. The particular design of the communication subsystem is dependent upon the communication network and associated wireless communications protocols with which the device is intended to operate.

The electronic device 1300 includes a microprocessor 1302 that controls the overall operation of the electronic device 1352. The microprocessor 1302 interacts with the above-described communications subsystem elements and also interacts with other device subsystems such as non-volatile or flash memory 1306, random access memory (RAM) 1304, auxiliary input/output (I/O) device 1338, data port 1328, display 1334, keyboard 1336, speaker 1332, microphone 1330, a short-range communications subsystem 1320, a power subsystem 1322, and or any other device subsystems.

One or more sensors 1382 such as radio frequency current transformed discussed above are communicative coupled with the device 1300. Such devices or technology enable the conversion of EM information to an electric signal that is interpreted by microprocessor 1302.

A battery 1324 is connected to a power subsystem 1322 to provide power to the circuits of the electronic device 1352. The power subsystem 1322 includes power distribution circuitry for providing power to the electronic device 1300 and also contains battery charging circuitry to manage recharging the battery 1324. The power subsystem 1322 includes a battery monitoring circuit that is operable to provide status of one or more battery status indicators, such as remaining capacity, temperature, voltage, electrical current consumption, and the like, to various components of the electronic handheld 1300. There may be an external power connector 1326 electrically coupled to an external power supply 1354 as shown.

The data port 1328 is able to support data communications between the electronic device 1300 and other devices through various modes of data communications, such as high speed data transfers over optical communications circuits or over electrical data communications circuits such as a USB connection incorporated into the data port 1328 of some examples. Data port 1328 is able to support communications with, for example, an external computer or other device.

Data communication through data port 1328 enables a user to set preferences through the external device or through a software application and extends the capabilities of the device by enabling information or software exchange through direct connections between the electronic device 1352 and external data sources rather than via a wireless data communication network 1359. In addition to data communication, the data port 1328 provides power to the power subsystem 1322 to charge the battery 1324 or to supply power to the electronic circuits, such as microprocessor 1302, of the electronic device 1300.

Operating system software used by the microprocessor 1302 is stored in flash memory 1306. Further examples are able to use a battery backed-up RAM or other non-volatile storage data elements to store operating systems, other executable programs, or both. The operating system software, device application software, or parts thereof, are able to be temporarily loaded into volatile data storage such as RAM 1304. One example of data storage in RAM is time and expense environment 250. Data received via wireless communication signals or through wired communications are also able to be stored to RAM 1304.

The microprocessor 1302, in addition to its operating system functions, is able to execute software applications on the electronic device 1300. A predetermined set of applications that control basic device operations.

Further applications may also be loaded onto the electronic device 1300 through, for example, the wireless network 1350, an auxiliary I/O device 1338, data port 1328, short-range communications subsystem 1320, or any combination of these interfaces. Such applications are then able to be installed by a user in the RAM 1304 or a non-volatile store for execution by the microprocessor 1302.

In a data communication mode, a received signal such as a text message or web page download is processed by the communication subsystem, including wireless receiver 1312 and wireless transmitter 1310, and communicated data is provided the microprocessor 1302, which is able to further process the received data for output to the display 1334, or alternatively, to an auxiliary I/O device 1338 or the data port 1328. A user of the electronic device 1352 may also compose data items, such as email messages, using the keyboard 1336, which is able to include a complete alphanumeric keyboard or a telephone-type keypad, in conjunction with the display 1334 and possibly an auxiliary I/O device 1338. Such composed items are then able to be transmitted over a communication network through the communication subsystem.

For voice communications, overall operation of the electronic device 1300 is substantially similar, except that received signals are generally provided to a speaker 1332 and signals for transmission are generally produced by a microphone 1330. Alternative voice or audio I/O subsystems, such as a voice message recording subsystem, may also be implemented on the electronic device 1300. Although voice or audio signal output is generally accomplished primarily through the speaker 1332, the display 1334 may also be used to provide an indication of the identity of a calling party, the duration of a voice call, or other voice call related information, for example.

Depending on the conditions or statuses of the electronic device 1300, one or more particular functions associated with a subsystem circuit may be disabled, or an entire subsystem circuit may be disabled. For example, if the battery temperature is low, then voice functions may be disabled, but data communications, such as email, may still be enabled over the communication subsystem.

A short-range communications subsystem 1320 provides for data communication between the electronic device 1352 and different systems or devices, which need not necessarily be similar devices. For example, the short-range communications subsystem 1320 includes an infrared device and associated circuits and components or a Radio Frequency based communication module such as one supporting Bluetooth^{®} communications, to provide for communication with similarly-enabled systems and devices, including the data file transfer communications described above.

A media reader 1360 is able to be connected to an auxiliary I/O device 1338 to allow, for example, loading computer readable program code of a computer program product into the electronic device 1300 for storage into non-volatile memory such as flash memory 1306. One example of a media reader 1360 is an optical drive such as a CD/DVD drive, which may be used to store data to and read data from a computer readable medium or storage product such as computer readable storage media 1362. Examples of suitable computer readable storage media include optical storage media such as a CD or DVD, magnetic media, or any other suitable data storage device. Media reader 1360 is alternatively able to be connected to the electronic device through the data port 1328 or computer readable program code is alternatively able to be provided to the electronic device 1300 through the wireless network 1350.

### Non-Limiting Examples

Although specific examples of the subject matter have been disclosed, those having ordinary skill in the art will understand that changes can be made to the specific examples without departing from the spirit and scope of the disclosed subject matter. The scope of the disclosure is not to be restricted, therefore, to the specific examples, and it is intended that the appended claims cover any and all such applications, modifications, and examples within the scope of the present disclosure.

What is claimed is:

1. A method of detecting anomalous electrical equipment operating conditions, the method comprising:
receiving zero span data from a receiver while the receiver is receiving Radio Frequency (RF) ElectroMagnetic Interference (EMI) energy emitted by a target electrical equipment at a detected frequency;
analyzing, by a data driven defects identification method, the zero span data received from the receiver;
determining, based on the analysis of the zero span data, whether or not a likely defect of the target electrical equipment exists; and
providing, based on determining a likely defect of the target electrical equipment exists, an indication of the likely defect.

2. The method of claim 1, further comprising:
receiving, over a specific RF spectrum, the RF EMI energy emitted by the target electrical equipment; and
determining the detected frequency by identifying, based on a comparison of the RF EMI energy to an EMI signature of the target electrical equipment, a spectral component at the detected frequency that is outside of the EMI signature.

3. The method of claim 1, wherein analyzing the zero span data comprises:
normalizing the zero span data; and
low pass filtering the normalized zero span data.

4. The method of claim 3, wherein analyzing the zero span data received further comprises reducing samples within the zero span data using data reduction methods.

5. The method of claim 1, wherein the data driven defects identification method comprises a data driven defects identification method to identify an exciter misfire defect that comprises:
identifying amplitude peaks in the zero span data that are separated by integer multiples of 2.812 milliseconds (mS);
creating a histogram of amplitude peaks in the zero span data that are separated by minimum time durations that are integer multiples of 2.812 mS;
determining that amplitude peaks in the histogram are separated by integer multiples of 2.812 mS; and
determining, based on determining that amplitude peaks in the histogram are separated by integer multiples of 2.812 mS, the likely defect as an exciter misfire defect based on the histogram of amplitude peaks indicating peaks separated by minimum time durations that are integer multiples of 2.812 mS wherein the integer multiple is greater than one.

6. The method of claim 1, wherein the data driven defects identification method comprises analysis, by at least one machine learning model, of the zero span data, wherein the at least one machine learning model is trained to classify the zero span data as indicating one defect type within a plurality of defect types.

7. The method of claim 6, wherein the target electrical equipment comprises an electrical generator,
wherein the machine learning model comprises a plurality of machine learning models, wherein the plurality of machine learning models comprises:
a first random forest classification model trained to classify the zero span data as indicating a corona discharge defect; and
a second random forest classification model trained to classify the zero span data as indication an arcing defect; and
wherein determining whether or not a likely defect of the target electrical equipment exists is based on respective classifications of the first random forest classification model and the second random forest classification model.

8. The method of claim 7, further comprising, prior to analysis of the zero span data by the first random forest classification model:
determining a high energy segment within the zero span data;
reducing the zero span data the zero span data by retaining less than one third of samples within the zero span data, wherein the one third of samples include the high energy segment;
normalizing the zero span data; and
low pass filtering the zero span data.

9. The method of claim 8, wherein the low pass filtering comprises low pass filtering with a third order Butterworth lowpass filter.

10. The method of claim 7, further comprising, prior to analysis of the zero span data by the second random forest classification model:
determining a high energy segment within the zero span data;
reducing the zero span data the zero span data by retaining less than one twenty-fifth of samples within the zero span data, wherein the one twenty-fifth of samples include the high energy segment;
normalizing the zero span data; and
low pass filtering the zero span data.

11. The method of claim 10, wherein the low pass filtering comprises low pass filtering with a sixth order Butterworth lowpass filter.

12. A system for detecting anomalous electrical equipment operating conditions, the system comprising:
a processor;
a memory, communicatively coupled to the processor;
a receiver configured to, when operating, receive Radio Frequency (RF) ElectroMagnetic Interference (EMI) energy emitted by a target electrical equipment;
an EMI signal processor, coupled to the processor and the memory, configured to, when operating:
receive zero span data from the receiver while the receiver is receiving RF EMI energy at a detected frequency;
analyze, by a data driven defects identification method, the zero span data received from the receiver;
determine, based on the analysis of the zero span data, whether or not a likely defect of the target electrical equipment exists; and
provide, based on a determination that a likely defect of the target electrical equipment exists, an indication of the likely defect.

13. The system of claim 12, wherein the EMI signal processor, when operating, is further configured to analyze the zero span data by at least:
normalizing the zero span data; and
low pass filtering the normalized zero span data.

14. The system of claim 12, wherein the EMI signal processor, when operating, is configured to analyze the zero span data to identify an exciter misfire defect by at least:
identifying amplitude peaks in the zero span data that are separated by integer multiples of 2.812 milliseconds (mS);
creating a histogram of amplitude peaks in the zero span data that are separated by minimum time durations that are integer multiples of 2.812 mS; and
identifying the likely defect as an exciter misfire defect based on the histogram of amplitude peaks indicating peaks separated by minimum time duration that are integer multiples of 2.812 mS wherein the integer multiple is greater than one and based on identifying amplitude peaks in the zero span data that are separated by integer multiples of 2.812 mS.

15. The system of claim 12, wherein the data driven defects identification method comprises analyzing the zero span data by at least one machine learning model that is trained to classify the zero span data as indicating one defect type within a plurality of defect types.

16. The system of claim 15, wherein the target electrical equipment comprises an electrical generator,
wherein the at least one machine learning model comprises a plurality of machine learning models comprising:
a first random forest classification model trained to classify the zero span data as indicating a corona discharge defect; and
a second random forest classification model trained to classify the zero span data as indication an arcing defect; and
wherein the EMI signal processor, when operating, is further configured to determine whether or not the likely defect of the target electrical equipment exists is based on respective classifications of the first random forest classification model and the second random forest classification model.

17. The system of claim 16, wherein the EMI signal processor, when operating, is further configured to, prior to analysis of the zero span data by the first random forest classification model:
determine a high energy segment within the zero span data;
reduce the zero span data the zero span data by retaining less than one third of samples within the zero span data, wherein the one third of samples include the high energy segment;
normalize the zero span data; and
low pass filter the zero span data.

18. The system of claim 17, wherein the low pass filtering comprises low pass filtering with a third order Butterworth lowpass filter.

19. The system of claim 16, wherein the EMI signal processor, when operating, is further configured to, prior to analysis of the zero span data by the second random forest classification model:
determine a high energy segment within the zero span data;
reduce the zero span data, the zero span data by retaining less than one twenty-fifth of samples within the zero span data, wherein the one twenty-fifth of samples include the high energy segment;
normalize the zero span data; and
low pass filter the zero span data.

20. The system of claim 19, wherein the low pass filtering comprises low pass filtering with a sixth order Butterworth lowpass filter.
